(19) United States
(12) Patent Application Publication
(10) Pub. No.: US 2025/0271486 A1
(43) Pub. Date: Aug. 28, 2025

(54) METHOD FOR CLASSIFICATION AND DETECTION OF FAULTS OF A MICROGRID AND A FAULT DETECTING SYSTEM COUPLED TO MICROGRID

(71) Applicant: KING FAHD UNIVERSITY OF PETROLEUM AND MINERALS, Dhahran (SA)

(72) Inventors: Mohammed Taher Ali ALSABA, Dhahran (SA); Mohamed Ali ABIDO, Dhahran (SA)

(73) Assignee: KING FAHD UNIVERSITY OF PETROLEUM AND MINERALS, Dhahran (SA)

(21) Appl. No.: 18/589,618

(22) Filed: Feb. 28, 2024

(51) Int. Cl. G01R 31/08; G06N 3/045; G06N 3/092

(52) U.S. Cl. CPC G01R 31/088; G01R 31/086; G06N 3/045; G06N 3/092

(57) ABSTRACT

A method for the classification and detection of faults in a microgrid having a distance relay, includes measuring the first plurality of voltage signals and the first plurality of current signals of the microgrid, calculating a plurality of fault-loop impedance signals, comparing the plurality of fault-loop impedance signals and a plurality of reference impedance values, inputting the plurality of difference values to a convolutional neural network (CNN)-gated recurrent unit (GRU) hybrid model, generating a reference tripping signal, defining a deep reinforcement learning (DRL) agent for a deep reinforcement learning (DRL) model. The method further includes processing a second plurality of voltage signals and current signals of microgrid and classifying the one or more fault signals into one or more fault types.

### STATEMENT OF PRIOR DISCLOSURE BY AN INVENTOR

Aspects of the present application were described in “An Efficient Machine Learning Model for Microgrid Fault Detection and Classification: Protection Approach,” Mohammed AlSaba, Mohammad Abido, 2023 IEEE Power & Energy Society General Meeting (PESGM), 16-20 Jul. 2023, which is incorporated herein by reference in its entirety.

### BACKGROUND

### Technical Field

The present disclosure is directed to a method and system for fault identification in a protection system of a microgrid, more particularly, to method for the classification and detection of faults in a microgrid and a fault-detecting system coupled to a microgrid.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Generally, microgrids offer many technical and financial benefits to existing power distribution networks, such as increasing the resiliency of power delivery, reducing power interruptions and voltage drops, and increasing load availability by integrating clean and cheap renewable energy resources. Microgrids also present many technical challenges including system stability, reliability, operational protection, and control challenges, especially during an microgrid islanded mode of operation. Microgrid islanded mode is more challenging due to the low level of short circuit current and changing network topologies. The protection system is the focus of the present technology as the protection system must be capable of identifying faults, isolating faulty sections, and ensuring continuity of the power supply to unaffected loads. Various studies in the literature have presented approaches to resolve some of the protection challenges to mitigate faults in alternating current (AC) microgrids including adaptive relay setting, fault current limiters, and fault detection and identification.

In an adaptive overcurrent-relaying scheme independent of external controllers and communication to estimate relay settings with an optimal photovoltaic (PV) capacity allocation method, the solution is cheaper than distance or differential protection and has no dependency on communication. However, the method limits the installation of PV at each bus, and the PV allocation is dependent on existing protection relay settings. A simple overcurrent deep reinforced machine learning adaptive setting was introduced with renewable energy resources (RES) in the microgrid. The agent is an overcurrent relay that takes the current measurement as an observation and takes action to trip its circuit breaker. The agent then receives its rewards based on correct or incurrent tripping of the circuit breaker. Thus, a positive reward is given if the fault is in the zone of the overcurrent relay and a negative reward is given if the fault is outside the zone of the overcurrent relay. The model is not tested for stability against faults in the reverse direction or noise levels. In an adaptive directional overcurrent and distance protection based on a machine-learning artificial neural network and support vector machine (ANN-SVM), the grid operating mode is detected using the ANN-SVM, and the directional overcurrent relay operating times are formulated as an optimization function that minimizes the operating time subject to the limits of backup relay coordination time. The directional overcurrent and the distance protection relays switch the setting groups based on the ANN SVM identification for the microgrid operating mode. The distance and differential protection relays are normally more sensitive, and selective, and have faster operating times than overcurrent relays. In an adaptive protection superimposed negative sequence admittance method for detecting unbalanced faults based on the impact factor of different distributed generators (DGs) in the network was introduced. The method is dependent on negative sequence components. In inverter-based resources, the negative sequence fault current depends on the inverter control, and for type IV wind and solar PV, the negative sequence current is typically low.

The fault current limiter is an additional high impedance that is added during fault conditions to limit the fault current damage to the power equipment. The fault current limiters do not clear the fault and are usually bulky, and expensive equipment. To mitigate these disadvantages, a positive and negative sequence limiter is proposed in the inverter controller of the distributed generation by limiting the output current and active power. However, the soft limiting technique is slow because it cannot limit the fault current within the first cycle after the fault. In known techniques, the faulty section is detected based on a residual signal generated by analyzing the fault current signal using a Kalman filter. Available fault current limiters are activated at the faulty section, and the faulty section is later segregated from the interconnected distributed generation. However, the coordination of the limiter with the existing overcurrent relays or distance relays was not investigated, and the effect of the limiter on the protection relays was not studied.

In another known technique, wavelet transformation coupled with a deep learning gated recurrent unit fault is used to identify the fault type, and its location is presented. The wavelet transformation is used to extract the feature of the measured current. However, the technique does not discuss the interaction with the protection relays or examine high-impedance faults. Hilbert Huang transformation coupled with empirical mode decomposition (EMD), variational mode decomposition (VMD), and empirical wavelet transform (EWT) techniques were used for feature extraction of the measured differential current signal. Additionally, ensemble classifiers along with a majority voting system are used for obtaining optimal results. The model was also tested with various noise penetration levels. In earlier prior art, fault current identification is defined as an agent action. The agent receives the three-phase voltage magnitude of all nodes, the active power of all generators, and the reference signal from the environment as observations. Based on the fault current identifications made by the agent, the agent collects positive rewards if the identification is correct. Although the DRL was able to identify fault types, the process of utilizing DRL for identification and classification is not recommended and is not efficient. The gaps identified in the currently known techniques associated with protection relays used in AC microgrids including a high sampling rate required for better classification accuracy of high-impedance faults. The methods are computationally expensive, high impedance faults are not investigated in most papers, and performance accuracy based on protection evaluation criteria is not quantified. The effectiveness of the proposed methods under noisy conditions is not explored and prototyping and hardware in loop testing for real-time applications have not been investigated.

Accordingly, it is one object of the present disclosure to provide a method for the classification and detection of faults in a microgrid and a fault-detecting system coupled to the microgrid. The present disclosure describes an efficient reinforcement learning model for fault detection and a convolutional neural network (CNN)-gated recurrent unit (GRU) hybrid model for fault classification. The present disclosure is adaptable to AC microgrid topology changes, bidirectional power flow, fault current levels, renewable energy sources (RES) fault infeed, stability under normal conditions, and fast tripping.

### SUMMARY

In an exemplary embodiment, a method for the classification and detection of faults in a microgrid is described. The microgrid includes a distance relay, including measuring a first plurality of voltage signals and a first plurality of current signals of the microgrid. Each of the first plurality of voltage signals and each of the first plurality of current signals are a set of data points sequenced in time. The method also includes calculating a plurality of fault-loop impedance signals from the first plurality of voltage signals and the first plurality of current signals. The method also includes comparing the plurality of fault-loop impedance signals and a plurality of reference impedance values to generate a plurality of difference values. The method also includes inputting the plurality of difference values to a convolutional neural network (CNN)-gated recurrent unit (GRU) hybrid model and generating a reference tripping signal. The method also includes inputting the plurality of difference values to a processing circuitry of the distance relay and generating a relay tripping signal. The method also includes defining a deep reinforcement learning (DRL) agent for a deep reinforcement learning (DRL) model using a plurality of magnitude values and a plurality of phase angle values of the plurality of fault-loop impedance signals. The method also includes inputting the reference tripping signal and the relay tripping signal to the deep reinforcement learning (DRL) agent of the deep reinforcement learning model. The method also includes performing an action-reward process using the deep reinforcement learning (DRL) agent for training the deep reinforcement learning model. The method also includes processing a second plurality of voltage signals and a second plurality of current signals of the microgrid using the trained deep reinforcement learning (DRL) model for detecting one or more fault signals. The method also includes classifying the one or more fault signals into one or more fault types using the convolutional neural network (CNN)-gated recurrent unit (GRU) hybrid model.

In another exemplary embodiment, a fault detection system coupled to a microgrid is described. A fault detection system includes a first processing circuitry configured to implement a first process using a deep reinforcement learning model. A fault detection system also includes a distance relay unit. A fault detection system also includes a second processing circuitry configured to implement a second process using a convolutional neural network-gated recurrent unit (CNN-GRU) hybrid model. The first process comprises the detection of one or more faults of the microgrid. The second process comprises classification of the one or more faults of the microgrid into one or more fault types.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 depicts a convolutional neural network and gated recurrent unit (CNN-GRU) architecture, according to an exemplary scenario;

FIG. 2 depicts an overview of reinforcement learning, according to an exemplary scenario.

FIG. 3 depicts a deep reinforcement learning (DRL) model architecture, according to certain embodiments;

FIG. 4 depicts a modified CIGRE medium voltage (MV) network, according to certain embodiments;

FIG. 5 depicts a grid mode tripping timing, according to certain embodiments;

FIG. 6 depicts an overview of communication with Raspberry PI, according to certain embodiments;

FIG. 7 depicts a flowchart of a method for classification and detection of faults of a microgrid, according to certain embodiments;

FIG. 8 depicts is an illustration of a non-limiting example of details of computing hardware used in the computing system, according to certain embodiments;

FIG. 9 is an exemplary schematic diagram of a data processing system used within the computing system, according to certain embodiments;

FIG. 10 is an exemplary schematic diagram of a processor used with the computing system, according to certain embodiments; and

FIG. 11 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about” and similar terms generally refer to ranges that include the identified value within a margin of 20%, 10%, or preferably 5%, and any values therebetween.

Aspects of the present disclosure describes an efficient reinforcement learning model for fault detection and a convolutional neural network and gated recurrent unit (CNN-GRU) hybrid model for fault classification. The model of the present disclosure can detect and classify low- and high-impedance faults. Also, the model is adaptable to AC microgrid topology changes, bidirectional power flow, fault current levels, RES fault infeed, stability under normal conditions, and fast tripping. The contributions of the present disclosure can be summarized as an accurate low and high-impedance fault detection and classification model that provides fast tripping. The present disclosure provides a novel DRL-based protection model based on local measurements that is less sensitive to noise and with a lower sampling rate for a low computational burden of the model.

Typically, distance protection relays provide fault coverage that is less independent of source impedance than overcurrent relays, inherently directional, and have good coverage for high impedance faults. Plain distance protection operates based on the six-loop impedance measurement of positive sequence voltages and currents. The complex values of fault-loop voltages and current signals for faults with negligible fault impedances are shown in Table 1, where

$$k = ( {Z}_{0} L - {Z}_{1} L ) / ( 3 \times {Z}_{1} L ) \qquad ( 1 )$$

k is the zero-sequence compensation factor,
Z₀L is the zero-sequence line impedance,
Z₁L is the positive-sequence line impedance,
m is the per-unit distance to fault, and
I₀ is the zero-sequence current.

TABLE 1
Fault impedance calculations

| | Positive-Sequence |
|---|---|
| Fault Type | Impedance Equation (mZ₁L=) |
| A-G | Vₐ/(Iₐ + k × 3 × I₀) |
| B-G | V_{b}/(Iₐ + k × 3 × I₀) |
| C-G | V_{c}/(Iₐ + k × 3 × I₀) |
| A-B or A-B-G | V_{ab}/I_{ab} |
| B-C or B-C-G | V_{bc}/I_{bc} |
| C-A or C-A-G | V_{ca}/I_{ca} |
| A-B-C | Any of the following: |
| or | V_{ab}/I_{ab}, V_{bc}/I_{bc}, V_{ca}/I_{ca} |
| A-B-C-G | |

The distance protection challenges in AC microgrids are the motivations and focus of the distance protection relay, as the protection system must respond to fault currents in microgrids in both grid-connected and islanded modes. Operating microgrids in islanded mode is more challenging due to the low level of short circuit current and changing network topologies. The protection system must be capable of identifying faults, isolating the faulty sections, and ensuring continuity of the power supply to unaffected loads. The distance protection relays have many challenges including dynamic distribution network configuration changes between the islanded and grid-connected mode, hence adaptive distance protection needs to be implemented. Increased fault current levels contributed by RES during grid-connected mode and low level of short circuit current in islanded mode operation affect the feeder distance minimum current threshold setting. Increased fault current DC offset contributed by the RES affects the fault current magnitude and distance protection operating time, and the infeed current affects distance protection due to the penetration of RES.

According to an embodiment, a fault classification and detection model based on a convolutional neural network-gated recurrent unit (CNN-GRU) hybrid model and deep reinforcement learning (DRL) with a focus on deep Q-network (DQN) (DRL-DQN) model is disclosed. The models are based on the 32 samples per cycle local measurement of three-phase voltages and currents. The DRL-DQN model accurately detects high- and low-impedance faults protects the microgrid and increases the overall reliability of the microgrid. The CNN-GRU hybrid model accurately classifies those faults and indicates the microgrid operating conditions. The simulation results for the CIGRE MV AC microgrid with different renewable energy resources (RES) penetration showed that injecting a practical level of noise has a small impact on most models and the reverse fault analysis is the main factor affecting the models' accuracy. To show the practical capabilities of the models in real-time, the model was deployed, and HIL was tested with a Raspberry PI smart microcontroller as a hardware prototype. The simulation results for the Raspberry PI showed the model could provide stable results during different microgrid operational conditions.

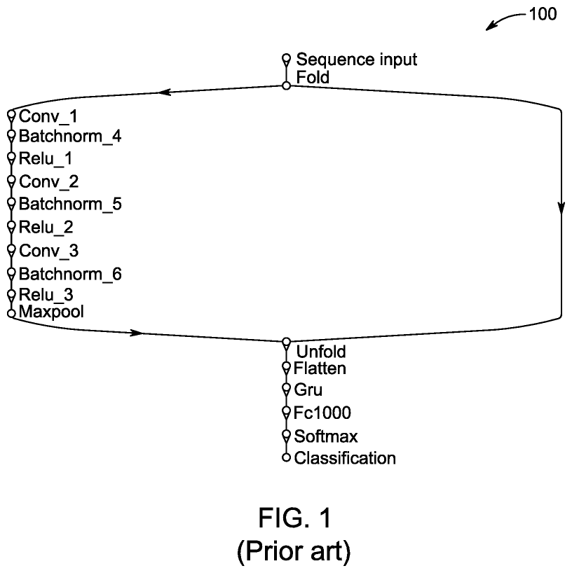

FIG. 1 depicts a convolutional neural network and gated recurrent unit (CNN-GRU) architecture, according to an exemplary scenario. Deep learning is a subset of machine learning and is broadly divided into supervised, unsupervised, and semi-supervised learning models. The supervised deep learning model is used to detect and classify the fault current efficiently compared to other machine learning models. Usually, convolution neural networks (CNN) are used because CNNs have built-in feature extraction. Since protection relays typically have a sampling rate of 1.6 kilohertz (KHz) (32 samples per cycle for 50 Hz systems), the architecture of the CNN model of the present technology is designed with an image input layer of size [32,8,1]. Therefore, the hardware implementation of the model of the present technology will fit with an analog-to-digital converter buffer size of 32 samples matching with CNN architecture and relay sampling rate. After several model runs, the deep CNN architecture used for fault classification that gives the best model performance consists of the Sequence input layer of size [32,8,1], Convolution layer: filter size 2×2, No. Filter=16, Batch normalization layer, Rectified linear unit (ReLU) activation layer, Convolution layer: filter size 2×2, No. Filter=32, Batch normalization layer, ReLU activation later, Convolution layer: filter size 2×2, No. Filter=64, Batch normalization layer, ReLU activation later, Max pooling layer of size [2,1], Fully connected layer, SoftMax layer and Classification layer output. The hybrid CNN-gated recurrent unit (GRU) model 100 is shown in FIG. 1 with convolution layers configurations similar to the CNN. Since the voltage and current measurements are time series data (sequence of data points indexed in time), the GRU layer is added to learn dependencies between time steps in time series and sequence data. As shown in FIG. 1, the data is split into two paths. One path with a sequence folding layer that converts the voltage and current time series data to a batch of images to perform convolution operations by the CNN layer. The other path is to deliver the voltage and current time series data unchanged to the GRU layer. The two ends of the path split are connected using a connection layer and passed to the sequence unfolding layer to restore the sequence structure of the data. The data are then flattened using the flattened layer and conveyed to the GRU for classification. The CNN-GRU hybrid model 100 is used for DRL model fault detection model training, and fault type classification.

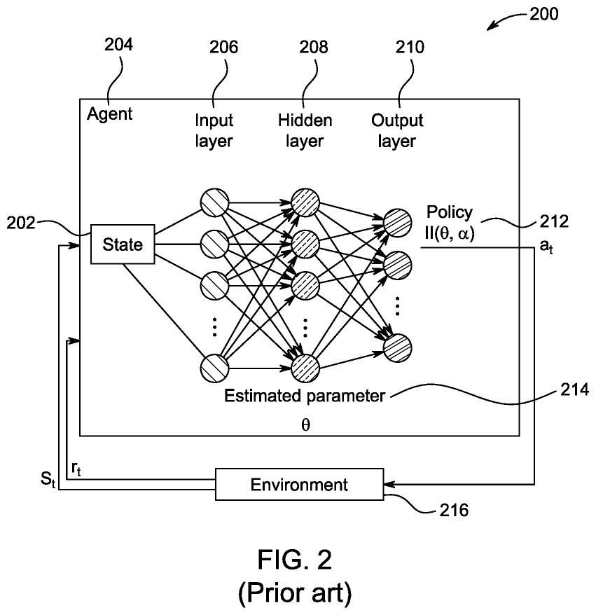

FIG. 2 depicts an overview of reinforcement learning, according to an exemplary scenario. The reinforcement learning 200 studies the use of the DRL model that is trained based on parallel actions of distance relay and the CNN-GRU hybrid model. In reinforcement learning 200, the learner (agent) is not told which actions to take but instead must discover which actions yield the most reward by trying them. It also means that an agent receives observation information from the environment, takes actions after learning, and based on the correct actions the agent collects the rewards or negative rewards for incorrect actions. The elements of reinforcement machine learning are the state 202, the environment 216, the agent 204, the policy 212, and the reward and value function. The environment 216 in reinforcement learning contains everything beyond the agent and it can be the system dynamics, the plant, the power system network, or the system factors.

The environment 216 is usually defined as a Markov decision process (MDP). Both the observation samples and the action signals can be either discrete or continuous and the environment model is the model to be designed for the agent to operate. The reward is the system that guides the learning process toward the positive desired actions of the agent. Usually, the reward is positive when the observation samples for a particular action are desired. Subsequently, the agent renews the policy as per the received rewards. The agent rule is being trained to make desired actions. The agent contains two main elements the policy and the learning algorithm. The policy 212 is broadly defined as a mapping process that chooses agent actions based on the sampled observations. The policy 212 can be a function, a lookup table, or a function approximator such as a deep neural network. The agent can rely on a critic and/or an actor to tell the agent how good the past action was and comprises input layer 206, hidden layer 208 and output layer 210. In this study, many agent types and classifications have been adopted with a focus on deep Q-network (DQN) agent used with discrete actions. The DON agent is trained based on maximizing the long-term expected reward as:

$${a}_{tmax} = arg {max}_{a} Q * ( ∅ ( {s}_{t} ) , a , θ ) \qquad ( 2 )$$

$${y}_{t} = {r}_{t} + {γmax}_{{a}^{′}} Q ( {∅}_{t + 1} , {a}^{′} , θ ) \qquad ( 3 )$$

where,
aₜₘₐₓ is the action at time step t that yields the maximum long-term expected reward;
Q* is an action-value function (the critic) of the sequence states (observations) and the actions;
Ø (sₜ) is a fixed-length function representation of the sequence states sₜ at time step t
a is the critic action parameter;
θ 214 is the weight of the deep neural network;
γₜ is the value function target;
γ is the discount factor;
Øₜ₊₁ is the next function representation of the sequence states sₜ₊₁ at time step t+1;
à is the optimal action to be selected;
rₜ is the reward at time step t;
   Subsequently, the stochastic gradient descent is used to update the weights of the deep neural network at each iteration t using the loss function:

$$L = [ {y}_{t} - {Q ( {∅}_{t} , {a}_{t} ; θ )}^{2} ] \qquad ( 4 )$$

The equation (4) can be solved using the gradient steepest descent method of the least-mean-square algorithm.

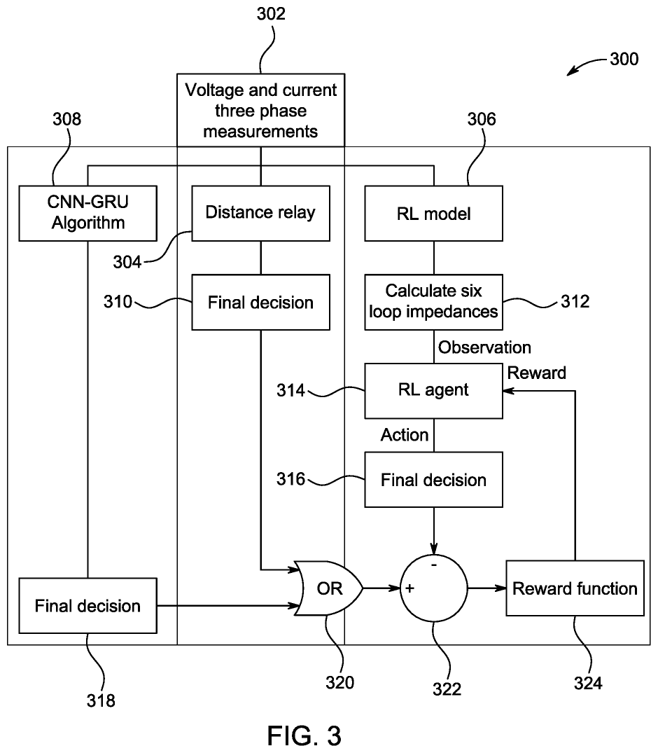

FIG. 3 depicts a deep reinforcement learning (DRL) model architecture 300, according to certain embodiments. The present technology advises against using reinforcement learning for classification problems since it is not the most efficient approach when compared to deep learning, ensemble methods, and support vector machines (SVMs). Thus, the deep reinforcement learning (DRL) model architecture 300 is proposed to model the reinforcement model as an intelligent fault detector. The deep reinforcement learning (DRL) model architecture 300 is based on converting the measured three-phase voltages and currents to the complex value of fault-loop impedance signals presented in Table 1. At step 302, three-phase measurements of voltage and current are performed. Then, those signals are fed as observation values to the reinforcement learning agent comprising distance relay 304, RL model 306, and CNN-GRU algorithm 308. At step 310 a final decision is taken. At step 312, the six-loop impedances are calculated. At step 314, the DRL agent is defined with twelve continuous observations namely the magnitude and the phase angles of the impedances Z_{AG}, Z_{BG}, Z_{CG}, Z_{AB}, Z_{BC}, and Z_{CA}. During fault conditions, the tripping signal of the distance relay 304 in parallel with the tripping signal of the CNN-GRU hybrid model 308 is used as a reference action signal for the reward function 324 of the DRL agent 314 during the training process as shown in FIG. 3. The DRL agent 314 is trained in parallel by actions of the distance relay 304 and the CNN-GRU hybrid model 308. The actions of the DRL agent 314 are defined as discrete values of either zero or one, where zero indicates no trip and one indicates a trip command. The final decision 310 of distance relay 304 and final decision 318 of CNN-GRU algorithm 308 are provided to OR-gate 320. The output of OR-gate 320 is combined 322 with final decision 316 of DRL agent 314 for reward function 324.

To guide the training of DRL agents, a scalar reward was awarded to the DRL agent 314 for the correct action, and a negative reward value was awarded for incorrect the action. The DRL agent 314 correct actions are calculated based on the difference between the delayed DRL agent 314 actions (by one sample) and the action of the tripping signal of the parallel combination of the distance relay and the CNN-GRU hybrid model 308. The DRL model is computationally efficient based on a sampling frequency of 1.6 kHz (32 samples per cycle of a 50 Hz system) which is much lower than the sampling rate used in some studies.

The DRL model is expected to have enhanced high-impedance fault detection in comparison to the distance relay resistive reach. Additionally, the DRL model is expected to have a tripping time that is similar to or better than that of the plain distance relay for low-impedance faults and a tripping speed similar to or better than that of the CNN-GRU hybrid model 308 for high-impedance faults that is usually not covered by the distance relay. Similar to a plain distance relay, the DRL model is supervised by a directional (DIR) relay along with minimum operating threshold values of voltage and current for stability during reverse direction faults and false tripping during low load conditions, unfolded, flattened, and conveyed to GRU for classification as shown in FIG. 1.

The DRL model of the present technology is expected to have enhanced high-impedance fault detection in comparison to the distance relay resistive reach. The DRL model is also supervised by a directional overcurrent relay for detecting forward and reverse direction faults. The DIR will release the DRL action for forward current faults and block the DRL action for the reverse faults. Thus, the CNN-GRU hybrid model 308 is expected to be stable for all reverse direction faults without the need to train for the conditions of reverse direction faults and increase the model efficiency. The CNN-GRU hybrid model 308 is also equipped with independent CNN-GRU models for fault type classification. The independent CNN-GRU hybrid model 308 is supervised by the same DIR. The DRL model along with the CNN-GRU hybrid model 308 and DIR relay algorithms are implemented in the Raspberry Pi microcontroller as the hardware prototype.

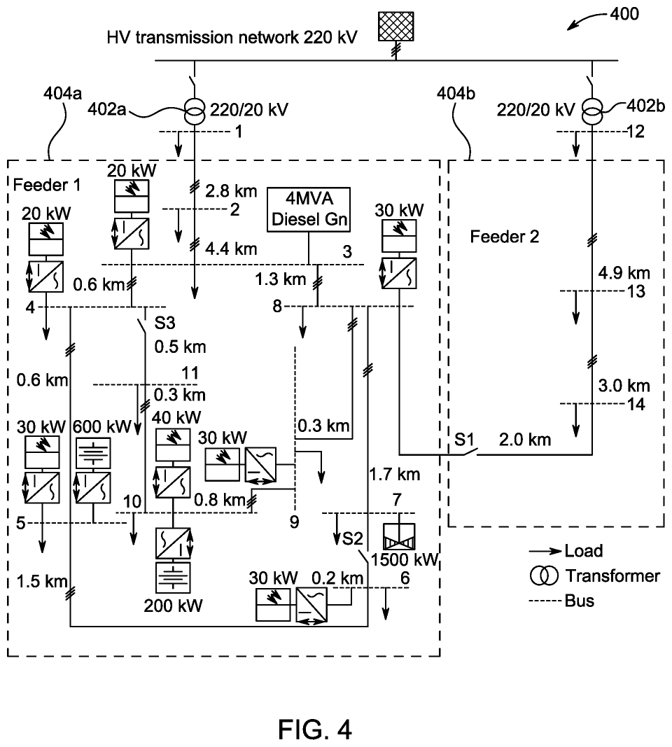

FIG. 4 depicts a modified CIGRE medium voltage (MV) network 400, according to certain embodiments. The modified CIGRE 14 bus medium voltage (MV) distribution network benchmark 400 European configuration shown in FIG. 4 is used as the test system. The network data used are the same with the addition of a 3.4 MW/2.12 MVAR diesel generator at Bus3 and RES as shown in Table 2. The CIGRE MV network has been modeled and simulated using MATLAB Simulink. The modified CIGRE 14 bus MV distribution network 400 benchmark comprises a pair of 220/20-kilo volts (KV) transformers 402a/402b feeder 1 404a and feeder 2 404b. The focus of the study is the line between Bus3 and Bus8. The training fault data are generated by applying all types of faults in both islanded and grid-connected modes with fault impedances of 0.01, 1, 5, and 20 ohms every 0.325 km generating fault records. The fault data are used to train the DRL model, and CNN-GRU for fault type classification. The voltage and current measurements are observed at Bus3. The total simulation duration is 0.08 sec (4 cycles) with faults applied at 0.04 sec. The CNN-GRU hybrid model 308 is a model with 32 samples per cycle. The CNN, ensemble classifier, k-nearest neighbors (KNN), support vector machine (SVM), and neural network (NN) were modeled as a benchmark to compare the accuracy with the CNN-GRU hybrid model 308. The CNN, ensemble model, KNN, and NN were designed for an input of 256 samples per cycle representing the instantaneous values of three-phase voltages and currents. All models have twenty-three classification categories including zero for startup conditions along with normal conditions and all fault types for classification of the islanded and grid-connected modes. The novel deep reinforcement learning model was modeled in MATLAB. The MATLAB Simulink environment was selected as the DRL dynamic environment. The faults data have been clustered to 43 faults using the dynamic time warping distance between signals clustering method and used for the training of the DRL model. The fault data have been flattened to one long episode and used to train a deep-Q-network (DQN)-DRL agent. Additionally, the actor-critic AC-DRL agent and proximal policy optimization proximal policy optimization (PPO-DRL) agent were modeled to compare the accuracy with the DQN-DRL model. Some of the DON DRL model hyperparameters are shown in Table 3. The DRL DON agent was trained on an AMD Ryzen 9 laptop with Radeon RTX 3060 Graphics and 16 GB RAM. The training converges in approximately three minutes for the sampled fault data. The protection relay performance is usually evaluated based on the following criteria comprising selectivity, robustness, speed, and new testing data. The relay shall operate to isolate the faulty section during fault conditions and the relay shall be stable during normal conditions. Thus, for all models, the performance accuracy under different cases including correct tripping, false tripping during normal conditions, and no tripping during a fault condition has been evaluated. The performance is also extended to false tripping for faults in the reverse direction. Selectivity criteria are used for fault detection and fault classification models. In real microgrid networks, there are many sources of noise injected into the secondary control cable including induced voltage from power cables close to the secondary control cable, primary equipment switching, and lightning transients. Therefore, for all models, the accuracy of detecting and classifying faults has been evaluated while injecting a random Gaussian white noise with a typical signal to noise ratio (SNR) ratio of 40 dB and 30 dB to the secondary measurements of three-phase voltages and currents.

TABLE 2
RES DATA

| | | Pmax |
|---|---|---|
| Node | RES type | [kW] |
| 3 | Photovoltaic | 20 |
| 4 | Photovoltaic | 20 |
| 5 | Photovoltaic | 30 |
| 5 | Battery | 600 |
| 6 | Photovoltaic | 30 |
| 7 | Wind turbine | 1500 |
| 8 | Photovoltaic | 30 |
| 9 | Photovoltaic | 30 |
| 10 | Photovoltaic | 40 |
| 10 | Battery | 200 |

TABLE 3
DRL - DQN model hyperparameters

| Parameter | Value | Parameter | Value |
|---|---|---|---|
| Sample time | 0.005 | Max Steps Per Episode | 6532 |
| Discount Factor | 0.99 | Mini Batch Size | 64 |
| Experience Buffer | 10000 | Learning rate | 0.01 |
| Length | | | |

The function of the relay is to isolate faults as fast as possible to avoid voltage collapse and to ensure the continuity of the power supply. The speed of the DRL model tripping time is evaluated in comparison to the ideal tripping time. To evaluate the performance of the models, 242 new fault data were generated with a simulation duration of 0.08 sec (4 cycles) and faults applied at 0.04 sec. The fault is applied in both islanded and grid-connected modes with fault impedances of 0.05, 8, and 20 ohms every 0.433 km. Additionally, to test the stability of the models, 62 new bus faults were generated by applying faults at Bus4 in both islanded and grid-connected modes with fault impedances of 0.05, 8, and 20 ohms to evaluate the proposed models for faults in the reverse direction.

The selectivity accuracy associated with classifying and detecting forward faults is shown in Table 4 and Table 5 below. From the first part of Table 4 (accuracy without noise), it is noticeable that all classifying models are robust and accurate for classifying the new fault data while SVM models have slightly lower accuracies. Similar behavior was observed for the fault detection model. Furthermore, with an accuracy of 29.75%, we identify that the distance relay coverage for the high impedance faults is very limited as distance relays are typically set to 80% of the line impedance for zone1, 120% of the line impedance for zone2 and 200% of the line impedance for zone3.

TABLE 4
Forward faults classification models accuracy

| | Accuracy | | | | | |
|---|---|---|---|---|---|---|
| | without | | Accuracy with noise | | Accuracy with noise | |
| | noise (%) | | (SNR = 40 dB) (%) | | (SNR = 30 dB) (%) | |
| Model | Grid | Island | Grid | Island | Grid | Island |
| CNN-GRU | 100 | 100 | 100 | 100 | 100 | 100 |
| (Local Model) | | | | | | |
| CNN-GRU | 98.35 | 95.87 | 97.5 | 93.4 | 97.52 | 93.39 |
| (Raspberry Pi) | | | | | | |
| CNN | 100 | 100 | 100 | 100 | 100 | 100 |
| NN | 100 | 100 | 100 | 100 | 100 | 100 |
| KNN | 100 | 100 | 100 | 100 | 99.17 | 96.69 |
| SVM | 85.12 | 100 | 48.8 | 60.3 | 48.76 | 57.85 |
| ENS | 100 | 100 | 100 | 100 | 100 | 100 |

TABLE 5
Forward faults detection models accuracy

| | Accuracy | | Accuracy with | | Accuracy with | |
|---|---|---|---|---|---|---|
| | without | | noise | | noise | |
| | noise (%) | | (SNR = 40 dB) (%) | | (SNR = 30 dB) (%) | |
| Model | Grid | Island | Grid | Island | Grid | Island |
| DRL DQN | 100 | 100 | 100 | 100 | 100 | 100 |
| (Local Model) | | | | | | |
| DRL DQN | 100 | 100 | 100 | 100 | 100 | 100 |
| (Raspberry | | | | | | |
| Pi) | | | | | | |
| DRL PPO | 91.74 | 95.04 | 95 | 97.5 | 93.39 | 98.35 |
| DRL AC | 73.55 | 47.11 | 83.5 | 62 | 90.08 | 88.43 |
| Distance | 30.58 | 28.93 | 30.6 | 28.1 | 30.58 | 28.1 |
| Relay | | | | | | |

All models were tested for classifying data and detecting faults in islanded and grid-connected modes, during line shut-down (zero values), and normal operating conditions (no fault). The selectivity accuracy for the reverse direction faults with noise levels of SNR=30 dB is shown in Table 6 and Table 7. From Table 6, the CNN-GRU hybrid model 308 outperforms the other models because it is supervised by a directional relay. It is also noticeable that with a noise level of SNR=30 dB, the directional relay is sometimes cheated resulting in the misclassification of some of the reverse direction faults. Moreover, all other models misclassify the reverse faults because they are not initially trained for reverse faults and are without directional elements. Thus, the CNN-GRU hybrid is an efficient model because it is not practically possible to generate training data for all fault scenarios in the reverse direction. The fault detection models are also supervised by the DIR relay and are 100% stable for reverse direction faults as shown in Table 7 with small errors in the operation of the Raspberry Pi model.

TABLE 6
Reverse faults classification models accuracy

Accuracy with noise
(SNR = 30 dB) (%)

| Model | Grid | Island |
|---|---|---|
| CNN-GRU | 100 | 93.55 |
| (Local Model) | | |
| CNN-GRU | 100 | 93.55 |
| (Raspberry Pi) | | |
| CNN | 3.23 | 3.23 |
| NN | 35.48 | 9.68 |
| KNN | 38.71 | 9.68 |
| SVM | 32.26 | 3.23 |
| ENS | 38.71 | 22.58 |

TABLE 7
Reverse faults detection models accuracy

Accuracy with noise
(SNR = 30 dB) (%)

| Model | Grid | Island |
|---|---|---|
| DRL DQN | 100 | 100 |
| (Local Model) 502 | | |
| DRL DQN | 96.96 | 94.97 |
| (Raspberry Pi) 504 | | |
| DRL PPO 506 | 100 | 100 |
| DRL AC 508 | 100 | 100 |
| Distance Relay 510 | 100 | 100 |

By injecting random white Gaussian noise with SNR ratios of 40 dB and 30 dB respectively, into the secondary measurements of three-phase voltages and currents we evaluate the models' fault classification and detection accuracy under such conditions. It is noticed that when the noise is injected, there is a significant decrease in the SVM accuracy and there is almost no effect on the other models. A decrease was noticed in all models with an impractical noise level of 20 decibels (dB).

The fault detection models are also evaluated with the presence of noise conditions. From the second part of Table 5 (accuracy with noise), we notice that when noise is injected, there is almost no change in the accuracy for the DQN DRL models with the presence of noise as the DRL models are known for their robustness and reduced sensitivity to the presence of noise. There was an increase in the accuracy of the DRL PPO and DRL AC resulting from the increase in the fault current values due to noise. The distance relay accuracy almost did not change with the presence of noise as the distance relay model design is to be tuned to the fundamental frequency.

In an implementation, a fault detection system coupled to a microgrid is described. A fault detection system includes a first processing circuitry configured to implement a first process using a deep reinforcement learning model. A fault detection system also includes a distance relay unit. A fault detection system also includes a second processing circuitry configured to implement a second process using a convolutional neural network gated recurrent unit (CNN-GRU) hybrid model. The first process comprises the detection of one or more faults of the microgrid. The second process comprises classification of the one or more faults of the microgrid into one or more fault types. In an implementation, the fault detection system is configured to perform an action-reward training process for the deep learning model employing the convolutional neural network-gated recurrent unit (CNN-GRU) hybrid model and the distance relay. In an implementation, the microgrid comprises a three-phase power network including a high-voltage transmission network. In an implementation, the microgrid comprises renewable energy sources. In an implementation, the fault detection system also includes a directional overcurrent relay (DIR) coupled to the first processing circuitry and the second processing circuitry.

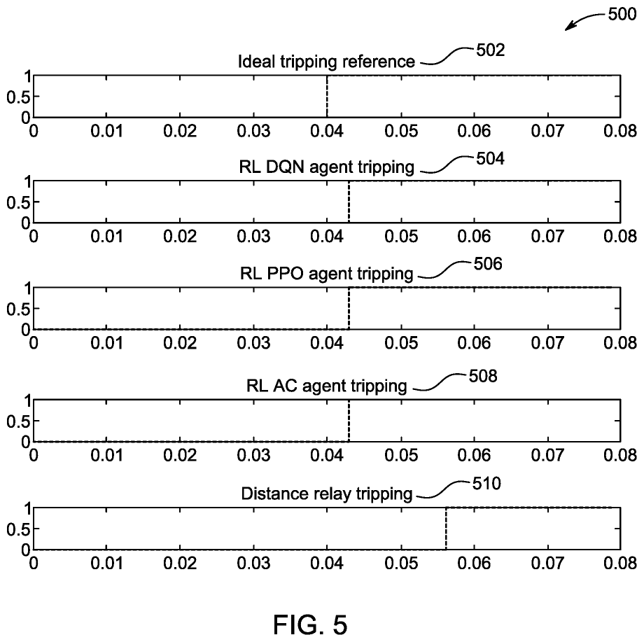

FIG. 5 depicts a grid mode tripping timing 500, according to certain embodiments. The speed of performance was measured at which each fault detection model tripped. Table 8 shows that the DRL DQN model outperforms the other model with an average tripping time of 0.011 sec after the fault is applied. Additionally, the distance relay has a variable tripping time, as the implemented delay time settings for the distance relay are zone 1=0 sec, zone 2=0.02 sec, and zone 3=0.04 sec. FIG. 5 shows a sample 500 of all model tripping behaviors for a grid mode for a three-phase close-in fault with a fault impedance of 0.005Ω. The behavior of different DRL agents is not the same; thus, modeling several DRL agents is preferred to identify the best DRL agent intended for the application. The accuracy of each DRL fault detection model is calculated by comparing the models' tripping actions with the ideal tripping behavior on a sample-to-sample comparison, as shown in Table 9. The RL DON agent tripping 504, RL proximal policy optimization (PPO) agent tripping 506, RL AC agent tripping 508, and distance relay tripping 510 are compared with the ideal tripping reference 502 to calculate the accuracy of DRL fault detection model. The DRL DON is the best model for fault detection as shown in FIG. 5.

TABLE 8
Fault detection models tripping time

| | Accuracy | | Accuracy with | | Accuracy with | |
|---|---|---|---|---|---|---|
| | without | | noise | | noise | |
| | noise (%) | | (SNR = 40 dB) (%) | | (SNR = 30 dB) (%) | |
| Model | Grid | Island | Grid | Island | Grid | Island |
| DRL DQN | 0.009 | 0.012 | 0.009 | 0.012 | 0.009 | 0.011 |
| (Local | | | | | | |
| Model) | | | | | | |
| DRL DQN | 0.009 | 0.013 | 0.009 | 0.013 | 0.009 | 0.012 |
| (Raspberry | | | | | | |
| Pi) | | | | | | |
| DRL PPO | 0.013 | 0.013 | 0.011 | 0.013 | 0.010 | 0.013 |
| DRL AC | 0.014 | 0.016 | 0.015 | 0.018 | 0.015 | 0.016 |
| Distance | 0.022 | 0.022 | 0.022 | 0.022 | 0.022 | 0.022 |
| Relay | | | | | | |

From Table 4, it can be concluded that a higher level of Gaussian white noise decreases classification accuracy for all classification models due to the distortion of data features resulting in a decrease in classification performances. In contrast, Table 9 draws a conclusion that a higher level of Gaussian white noise increases the fault detection accuracy for all detection models as the higher noise level increases the total short circuit values resulting in faster detection of the fault as already seen in Table 8.

TABLE 9
Forward faults sample to sample fault detection model accuracy

| | Accuracy | | Accuracy with | | Accuracy with | |
|---|---|---|---|---|---|---|
| | without | | noise | | noise | |
| | noise (%) | | (SNR = 40 dB) (%) | | (SNR = 30 dB) (%) | |
| Model | Grid | Island | Grid | Island | Grid | Island |
| DRL DQN | 88.54 | 84.85 | 88.76 | 84.78 | 89.14 | 85.58 |
| (Local Model) | | | | | | |
| DRL DQN | 87.62 | 84.1 | 88.03 | 84.02 | 88.61 | 84.92 |
| (Raspberry | | | | | | |
| Pi) | | | | | | |
| DRL PPO | 81.32 | 81.49 | 84.66 | 82.22 | 84.71 | 83 |
| DRL AC | 74.22 | 64.4 | 75.84 | 67.25 | 78.48 | 76.02 |
| Distance | 57.55 | 57.18 | 57.53 | 57.01 | 57.53 | 56.79 |
| Relay | | | | | | |

Consequently, by averaging all accuracies in the previous tables, the overall average accuracy for all models is indicated in Table 10 and Table 11. From Table 10, and based on the evaluation criteria above, it is noticed that the CNN-GRU hybrid is the best model for AC fault classification with an overall accuracy of 99.19%. The DRL DON is the best model for fault detection with an overall accuracy of 94.4% as shown in Table 11. Since most of the applied faults are high-impedance faults, from Table 10 and Table 11 it is noticeable that for all classification and detection models, the islanded mode high-impedance faults are more difficult to classify and detect than low-impedance faults.

TABLE 10
Faults classification models overall accuracy

| | Overall Accuracy | | |
|---|---|---|---|
| Model | Grid | Island | Tot |
| CNN-GRU | 100 | 98.39 | 99.19 |
| (Local Model) | | | |
| CNN-GRU | 98.35 | 94.05 | 96.2 |
| (Raspberry Pi) | | | |
| CNN | 75.81 | 75.81 | 75.81 |
| NN | 83.87 | 77.42 | 80.65 |
| KNN | 84.47 | 76.59 | 80.53 |
| SVM | 53.73 | 55.35 | 54.54 |
| ENS | 84.68 | 80.65 | 82.66 |

TABLE 11
Faults detection models overall accuracy

| | Overall Accuracy | | |
|---|---|---|---|
| Model | Grid | Island | Tot |
| DRL DQN | 95.21 | 93.6 | 94.4 |
| (Local Model) | | | |
| DRL DQN | 94.46 | 92.57 | 93.52 |
| (Raspberry Pi) | | | |
| DRL PPO | 90.12 | 91.09 | 90.61 |
| DRL AC | 82.23 | 72.17 | 77.2 |
| Distance Relay | 52.05 | 50.87 | 51.46 |

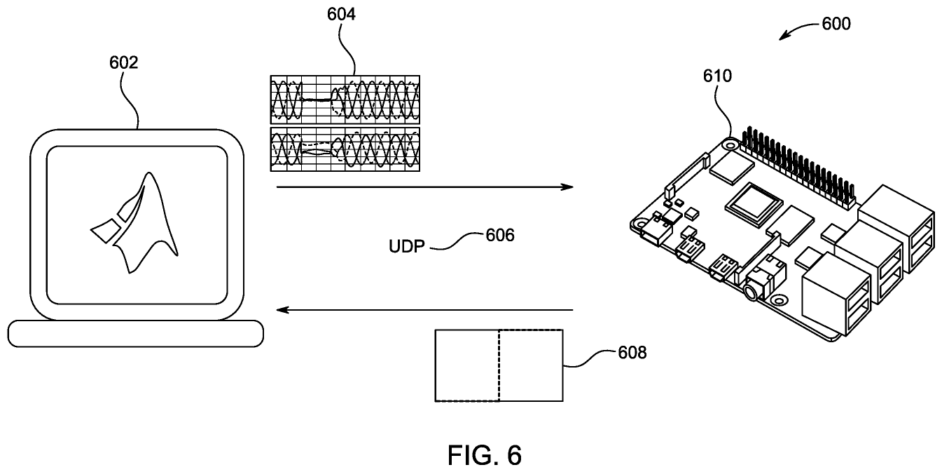

FIG. 6 depicts an overview of communication with Raspberry PI 600, according to certain embodiments. In the present technology, hardware in-the-loop testing is implemented to test the performance of the proposed CNN-GRU and the DRL DQN model in real-time using MATLAB Simulink Real-Time 602 and a Raspberry Pi 4 Model B 610. The Raspberry Pi 4 610 specifications are as follows: Broadcom BCM2711 quad-core Cortex-A72 (ARM v8) 64-bit SoC @ 1.8 GHz processor, 4 GB LPDDR4-3200 memory and gigabit ethernet. The ethernet port was used to establish UDP communication 606 between MATLAB Simulink Real-Time 602 and the Raspberry Pi 610 as shown in FIG. 6. The UPD protocol is selected due to its high-speed and low latency compared to the TCP/IP protocol with loop for testing of 604 and 608. MATLAB Simulink provided a hardware support package for the Raspberry Pi, which allowed converting the pre trained CNN-GRU and the DRL DON model to C++ code and then deploying the code on the Raspberry Pi. It should be noted that even while using the high-speed UPD protocol, there were small delays in the communication that could not be controlled by the user. These delays are one of the reasons for the slightly lower accuracies in Tables IV to X. The other reason was that for the local models and the Raspberry Pi models, different random Gaussian white noise values were simulated resulting in different accuracies.

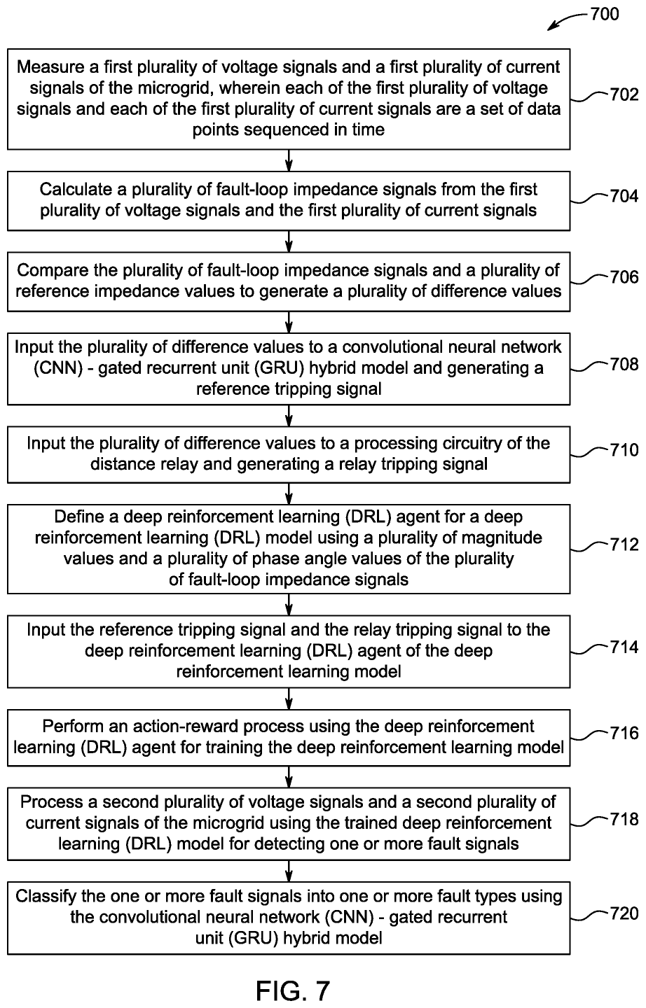

FIG. 7 depicts a flowchart of a method for classification and detection of faults of a microgrid, according to certain embodiments. At step 702, a first plurality of voltage signals and a first plurality of current signals of the microgrid are measured. Each of the first plurality of voltage signals and each of the first plurality of current signals is a set of data points sequenced in time. At step 704, a plurality of fault-loop impedance signals is calculated from the first plurality of voltage signals and the first plurality of current signals. At step 706, the plurality of fault-loop impedance signals and a plurality of reference impedance values are compared to generate a plurality of difference values. At step 708, the plurality of difference values is input to a convolutional neural network (CNN)-gated recurrent unit (GRU) hybrid model, and a reference tripping signal is generated. At step 710, the plurality of difference values is input to a processing circuitry of the distance relay and a relay tripping signal is generated. At step 712, a deep reinforcement learning (DRL) agent is defined for a deep reinforcement learning (DRL) model using a plurality of magnitude values and a plurality of phase angle values of the plurality of fault-loop impedance signals. At step 714, the reference tripping signal and the relay tripping signal is input to the deep reinforcement learning (DRL) agent of the deep reinforcement learning model. At step 716, an action-reward process is performed using the deep reinforcement learning (DRL) agent for training the deep reinforcement learning model. At step 718, a second plurality of voltage signals and a second plurality of current signals of the microgrid are processed using the trained deep reinforcement learning (DRL) model for detecting one or more fault signals. At step 720, the one or more fault signals are classified into one or more fault types using the convolutional neural network (CNN)-gated recurrent unit (GRU) hybrid model.

In an implementation, the method also includes measuring a plurality of voltage signals and a plurality of current signals to train the deep reinforcement learning (DRL) model. The method also includes processing the plurality of voltage signals and the plurality of current signals to detect one or more fault signals. The method also includes classifying the one or more fault signals into one or more fault types using the convolutional neural network (CNN)-gated recurrent unit (GRU) hybrid model. In an implementation, the method also includes classifying the plurality of faults, including inputting the second plurality of voltage signals and the second plurality of current signals to the convolutional neural network (CNN)-gated recurrent unit (GRU) hybrid model. The method also includes storing the second plurality of voltage signals and the second plurality of current signals as a first input. The method also includes encoding the first input to a plurality of image data points. The method also includes performing a set of convolution operations on the plurality of image data points using a convolutional neural network (CNN) model of the convolutional neural network gated recurrent unit (GRU) hybrid model in a first process to generate a first output.

The method also includes combining the first output of the first process and the first input resulting in a combined output. The method also includes restoring the combined output to a set of sequenced data points. The method also includes performing a flattening of data operation on the set of sequenced data points and generating a flattened data. The method also includes classifying the flattened data as one or more fault types using a gated recurrent unit (GRU) model of the convolutional neural network-gated recurrent unit (GRU) hybrid model in a second process. In an implementation, the deep reinforcement learning (DRL) model comprises a deep Q-network (DQN). In an implementation, performing the action-reward process includes generating a tripping signal using the deep reinforcement learning (DRL) agent, storing the tripping signal as an action of the deep reinforcement learning (DRL) agent, calculating a difference between the action of the deep reinforcement learning (DRL) agent and at least one signal of the reference tripping signal and the relay tripping signal, signifying the action of the deep reinforcement learning (DRL) agent as at least one of a correct action and an incorrect action based on the difference, awarding a positive scalar reward to the deep reinforcement learning (DRL) agent on signifying the action of the deep reinforcement learning (DRL) agent as the correct action and awarding a negative scalar reward to the deep reinforcement learning (DRL) agent on signifying the action of the deep reinforcement learning (DRL) agent as the incorrect action. In an implementation, the deep reinforcement learning (DRL) model utilizes a directional overcurrent relay (DIR).

In an implementation, each of the one or more faults is at least one of a forward direction fault and a reverse direction fault. In an implementation, the method also includes blocking a reverse direction fault using a directional overcurrent relay (DIR) of the deep reinforcement learning (DRL) model. In an implementation, the method also includes implementing one or more fault rectification actions after classifying one or more faults utilizing the convolutional neural network (CNN)-gated recurrent unit (GRU) hybrid model. In an implementation, the convolutional neural network (CNN)-gated recurrent unit (GRU) hybrid model utilizes a directional overcurrent relay (DIR). In an implementation, each of the one or more faults is at least one of a high impedance fault and a low impedance fault. In an implementation, each of the first plurality of voltage signals and the second plurality of voltage signals is a three-phase voltage signal. In an implementation, each of the first plurality of current signals and the second plurality of current signals is a three-phase current signal. In an implementation, each of the first plurality of voltage signals, the second plurality of voltage signals, the first plurality of current signals, and the second plurality of current signals comprises 32 samples per cycle. In an implementation, the microgrid comprises one or more renewable energy sources.

The present technology provides a novel deep reinforcement learning (DRL)-based distance protection capable of detecting low- and high-impedance faults in AC microgrids with renewable energy resources (RES). The present technology includes a convolutional neural network and gated recurrent unit (CNN-GRU) hybrid for fault classification. The present technology adopts a protection approach for accuracy, stability against reverse direction faults, and noise immunity for the evaluation of the proposed model. In this study, the performance of the model is evaluated by conducting prototype hardware in the loop (HIL) simulation using Raspberry Pi microcontroller and MATLAB Simulink. The results demonstrate the potential of the DRL-based distance relay to have higher detection sensitivity for power system faults compared to conventional ones. The experimental results are in full agreement with the simulation results showing the high accuracy of the DRL-based distance relay in detecting high-impedance faults. Moreover, it confirms the implementation of the model for real-time applications and achieves 93.52% overall accuracy.

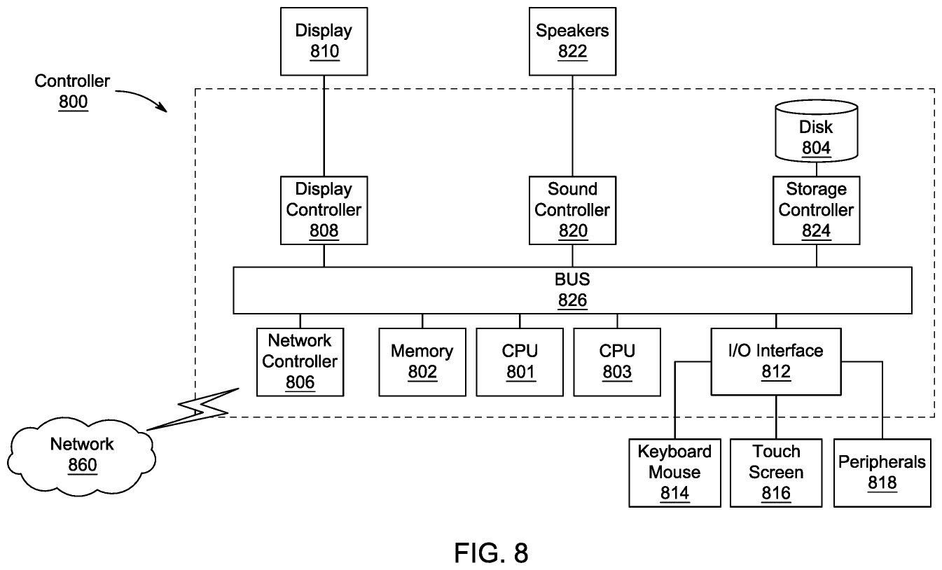

Details of the hardware description of the computing environment according to exemplary embodiments are described with reference to FIG. 8. In FIG. 8, a controller 800 is described is representative of the system 300 of FIG. 3 in which the controller is a computing device which includes a CPU 801 which performs the processes described above/below. The process data and instructions may be stored in memory 802. These processes and instructions may also be stored on a storage medium disk 804 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 801, 803 and an operating system such as Microsoft Windows 8, Microsoft Windows 9, Microsoft Windows 10,UNIX, Solaris, LINUX, Apple MAC-OS, and other systems known to those skilled in the art.

The hardware elements in order to achieve the computing device may be realized by various circuitry elements, known to those skilled in the art. For example, CPU 801 or CPU 803 may be a Xenon or Core processor from Intel of America or an Opteron processor from AMD of America, or may be other processor types that would be recognized by one of ordinary skill in the art. Alternatively, the CPU 801, 803 may be implemented on an FPGA, ASIC, PLD or using discrete logic circuits, as one of ordinary skill in the art would recognize. Further, CPU 801, 803 may be implemented as multiple processors cooperatively working in parallel to perform the instructions of the inventive processes described above.

The computing device in FIG. 8 also includes a network controller 806, such as an Intel Ethernet PRO network interface card from Intel Corporation of America, for interfacing with network 860. As can be appreciated, the network 860 can be a public network, such as the Internet, or a private network such as an LAN or WAN network, or any combination thereof and can also include PSTN or ISDN sub-networks. The network 860 can also be wired, such as an Ethernet network, or can be wireless such as a cellular network including EDGE, 3G, 4G and 5G wireless cellular systems. The wireless network can also be Wi-Fi, Bluetooth, or any other wireless form of communication that is known.

The computing device further includes a display controller 808, such as a NVIDIA GeForce GTX or Quadro graphics adaptor from NVIDIA Corporation of America for interfacing with display 810, such as a Hewlett Packard HPL2445w LCD monitor. A general purpose I/O interface 812 interfaces with a keyboard and/or mouse 814 as well as a touch screen panel 816 on or separate from display 810. General purpose I/O interface also connects to a variety of peripherals 818 including printers and scanners, such as an OfficeJet or DeskJet from Hewlett Packard.

A sound controller 820 is also provided in the computing device such as Sound Blaster X-Fi Titanium from Creative, to interface with speakers/microphone 822 thereby providing sounds and/or music.

The general-purpose storage controller 824 connects the storage medium disk 804 with communication bus 826, which may be an ISA, EISA, VESA, PCI, or similar, for interconnecting all of the components of the computing device. A description of the general features and functionality of the display 810, keyboard and/or mouse 814, as well as the display controller 808, storage controller 824, network controller 806, sound controller 820, and general purpose I/O interface 812 is omitted herein for brevity as these features are known.

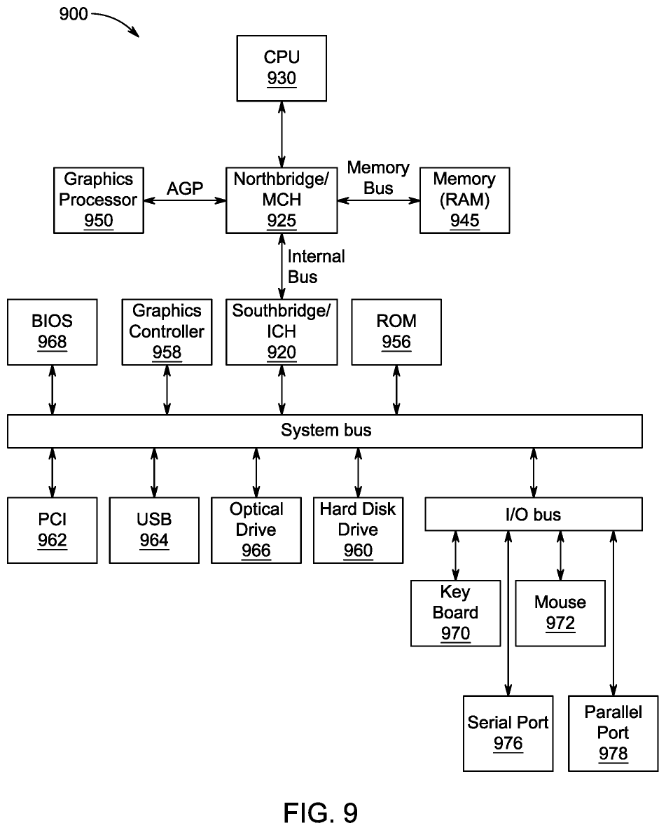

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 9.

FIG. 9 shows a schematic diagram of a data processing system 900, according to certain aspects of the present disclosure, for performing the functions of the exemplary aspects. The data processing system 900 is an example of a computer in which code or instructions implementing the processes of the illustrative aspects may be located.

In FIG. 9, data processing system 900 employs a hub architecture including a north bridge and memory controller hub (NB/MCH) 925 and a south bridge and input/output (I/O) controller hub (SB/ICH) 920. The central processing unit (CPU) 930 is connected to NB/MCH 925. The NB/MCH 925 also connects to the memory 945 via a memory bus, and connects to the graphics processor 950 via an accelerated graphics port (AGP). The NB/MCH 925 also connects to the SB/ICH 920 via an internal bus (e.g., a unified media interface or a direct media interface). The CPU Processing unit 930 may contain one or more processors and even may be implemented using one or more heterogeneous processor systems.

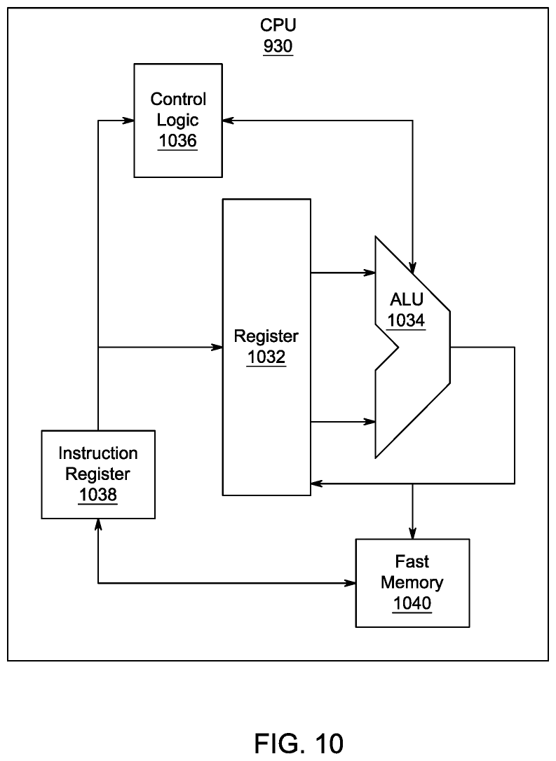

For example, FIG. 10 shows one implementation of CPU 930, according to an aspect of the present disclosure. In one implementation, the instruction register 1038 retrieves instructions from the fast memory 1040. At least part of these instructions are fetched from the instruction register 1038 by the control logic 1036 and interpreted according to the instruction set architecture of the CPU 930. Part of the instructions can also be directed to the register 1032. In one implementation the instructions are decoded according to a hardwired method, and in another implementation the instructions are decoded according to a microprogram that translates instructions into sets of CPU configuration signals that are applied sequentially over multiple clock pulses. After fetching and decoding the instructions, the instructions are executed using the arithmetic logic unit (ALU) 1034 that loads values from the register 1032 and performs logical and mathematical operations on the loaded values according to the instructions. The results from these operations can be feedback into the register and/or stored in the fast memory 1040. According to certain implementations, the instruction set architecture of the CPU 930 can use a reduced instruction set architecture, a complex instruction set architecture, a vector processor architecture, a very large instruction word architecture. Furthermore, the CPU 930 can be based on the Von Neuman model or the Harvard model. The CPU 930 can be a digital signal processor, an FPGA, an ASIC, a PLA, a PLD, or a CPLD. Further, the CPU 930 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 9, the data processing system 900 can include that the SB/ICH 920 is coupled through a system bus to an I/O Bus, a read only memory (ROM) 956, universal serial bus (USB) port 964, a flash binary input/output system (BIOS) 968, and a graphics controller 958. PCI/PCIe devices can also be coupled to SB/ICH 888 through a PCI bus 962.

The PCI devices may include, for example, Ethernet adapters, add-in cards, and PC cards for notebook computers. The Hard disk drive 960 and CD-ROM 966 can use, for example, an integrated drive electronics (IDE) or serial advanced technology attachment (SATA) interface. In one implementation the I/O bus can include a super I/O (SIO) device.

Further, the hard disk drive (HDD) 960 and optical drive 966 can also be coupled to the SB/ICH 920 through a system bus. In one implementation, a keyboard 970, a mouse 972, a parallel port 978, and a serial port 976 can be connected to the system bus through the I/O bus. Other peripherals and devices that can be connected to the SB/ICH 920 using a mass storage controller such as SATA or PATA, an Ethernet port, an ISA bus, a LPC bridge, SMBus, a DMA controller, and an Audio Codec.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry, or based on the requirements of the intended back-up load to be powered.

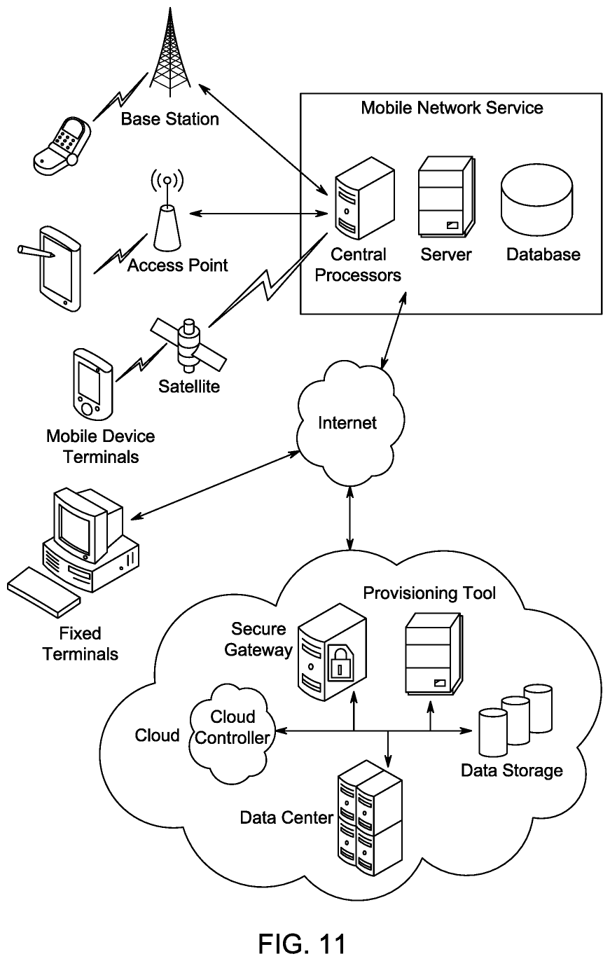

The functions and features described herein may also be executed by various distributed components of a system. For example, one or more processors may execute these system functions, wherein the processors are distributed across multiple components communicating in a network. The distributed components may include one or more client and server machines, which may share processing as shown in FIG. 11, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A method for classification and detection of faults of a microgrid, wherein the microgrid comprises a distance relay, comprising
measuring a first plurality of voltage signals and a first plurality of current signals of the microgrid, wherein each of the first plurality of voltage signals and each of the first plurality of current signals are a set of data points sequenced in time;
calculating a plurality of fault-loop impedance signals from the first plurality of voltage signals and the first plurality of current signals;
comparing the plurality of fault-loop impedance signals and a plurality of reference impedance values to generate a plurality of difference values;
inputting the plurality of difference values to a convolutional neural network (CNN)-gated recurrent unit (GRU) hybrid model and generating a reference tripping signal;
inputting the plurality of difference values to a processing circuitry of the distance relay and generating a relay tripping signal;
defining a deep reinforcement learning (DRL) agent for a deep reinforcement learning (DRL) model using a plurality of magnitude values and a plurality of phase angle values of the plurality of fault-loop impedance signals;
inputting the reference tripping signal and the relay tripping signal to the deep reinforcement learning (DRL) agent of the deep reinforcement learning model;
performing an action-reward process using the deep reinforcement learning (DRL) agent for training the deep reinforcement learning model;
processing a second plurality of voltage signals and a second plurality of current signals of the microgrid using the trained deep reinforcement learning (DRL) model for detecting one or more fault signals; and
classifying the one or more fault signals into one or more fault types using the convolutional neural network (CNN)-gated recurrent unit (GRU) hybrid model.

2. The method of claim 1, further comprising:
measuring a plurality of voltage signals and a plurality of current signals to train the deep reinforcement learning (DRL) model;
processing the plurality of voltage signals and the plurality of current signals to detect one or more fault signals; and
classifying the one or more fault signals into one or more fault types using the convolutional neural network (CNN)-gated recurrent unit (GRU) hybrid model.

3. The method of claim 1, wherein classifying the plurality of faults, comprising:
inputting the second plurality of voltage signals and the second plurality of current signals to the convolutional neural network (CNN)-gated recurrent unit (GRU) hybrid model;
storing the second plurality of voltage signals and the second plurality of current signals as a first input;
encoding the first input to a plurality of image data points;
performing a set of convolution operations on the plurality of image data points using a convolutional neural network (CNN) model of the convolutional neural network-gated recurrent unit (GRU) hybrid model in a first process to generate a first output;
combining the first output of the first process and the first input resulting in a combined output;
restoring the combined output to a set of sequenced data points;
performing a flattening of data operation on the set of sequenced data points and generating a flattened data; and
classifying the flattened data as one or more fault types using a gated recurrent unit (GRU) model of the convolutional neural network gated recurrent unit (GRU) hybrid model in a second process.

4. The method of claim 1, wherein the deep reinforcement learning (DRL) model comprises a deep Q-network (DQN).

5. The method of claim 1, wherein performing the action-reward process comprises:
generating a tripping signal using the deep reinforcement learning (DRL) agent;
storing the tripping signal as an action of the deep reinforcement learning (DRL) agent;
calculating a difference between the action of the deep reinforcement learning (DRL) agent and at least one signal of the reference tripping signal and the relay tripping signal;
signifying the action of the deep reinforcement learning (DRL) agent as at least one of a correct action and an incorrect action based on the difference;
awarding a positive scalar reward to the deep reinforcement learning (DRL) agent on signifying the action of the deep reinforcement learning (DRL) agent as the correct action; and
awarding a negative scalar reward to the deep reinforcement learning (DRL) agent on signifying the action of the deep reinforcement learning (DRL) agent as the incorrect action.

6. The method of claim 1, wherein the deep reinforcement learning (DRL) model utilizes a directional overcurrent relay (DIR).

7. The method of claim 1, wherein each of the one or more faults is at least one of a forward direction fault and a reverse direction fault.

8. The method of claim 1, further comprising blocking a reverse direction fault using a directional overcurrent relay (DIR) of the deep reinforcement learning (DRL) model.

9. The method of claim 1, further comprising
implementing one or more fault rectification actions after classifying the one or more faults utilizing the convolutional neural network (CNN)-gated recurrent unit (GRU) hybrid model.

10. The method of claim 1, wherein the convolutional neural network (CNN)-gated recurrent unit (GRU) hybrid model utilizes a directional overcurrent relay (DIR).

11. The method of claim 1, wherein each of the one or more faults is at least one of a high impedance fault and a low impedance fault.

12. The method of claim 1, wherein each of the first plurality of voltage signals and the second plurality of voltage signals is a three-phase voltage signal.

13. The method of claim 1, wherein each of the first plurality of current signals and the second plurality of current signals is a three-phase current signal.

14. The method of claim 1, wherein each of the first plurality of voltage signals, the second plurality of voltage signals, the first plurality of current signals, and the second plurality of current signals comprises 32 samples per cycle.

15. The method of claim 1, wherein the microgrid comprises one or more renewable energy sources.

16. A fault detection system coupled to a microgrid, comprising:
a first processing circuitry configured to implement a first process using a deep reinforcement learning model;
a distance relay unit;
a second processing circuitry configured to implement a second process using a convolutional neural network-gated recurrent unit (CNN-GRU) hybrid model;
wherein the first process comprises detection of one or more faults of the microgrid; and
wherein the second process comprises classification of the one or more faults of the microgrid into one or more fault types.

17. The fault detection system of claim 16, configured to perform an action-reward training process for the deep learning model employing the convolutional neural network-gated recurrent unit (CNN-GRU) hybrid model and the distance relay.

18. The fault detection system of claim 16, wherein the microgrid comprises a three-phase power network including a high voltage transmission network.

19. The fault detection system of claim 16, wherein the microgrid comprises renewable energy sources.

20. The fault detection system of claim 16, further comprises a directional overcurrent relay (DIR) coupled to the first processing circuitry and the second processing circuitry.
